(19) United States
(12) Patent Application Publication
(10) Pub. No.: US 2026/0262505 A1
(43) Pub. Date: Sep. 3, 2026

(54) MICROELECTRONIC DEVICE PACKAGE WITH INTEGRATED INDUCTOR AND SEMICONDUCTOR DEVICE

(71) Applicant: Texas Instruments Incorporated, Dallas, TX (US)

(72) Inventor: John Carlo Molina, Limay (PH)

(21) Appl. No.: 19/067,806

(22) Filed: Feb. 28, 2025

(51) Int. Cl. H01L 23/64; H01L 21/56; H01L 23/00; H01L 23/31

(52) U.S. Cl. CPC H10W 44/501; H10W 74/016; H10W 74/121; H10W 72/072; H10W 72/241; H10W 90/724; H10W 90/726

(57) ABSTRACT

An example apparatus includes: at least one semiconductor die flip chip mounted to the device side surface of a package substrate; conductive clips mounted on the package substrate and spaced from the semiconductor die, the conductive clips having a height greater than a thickness of the semiconductor die; a first layer of mold compound covering the semiconductor die, while the distal ends of the conductive clips are exposed; conductor portions mounted on the distal ends of the conductive clips, the conductor portions extending over and across the semiconductor die, the conductor portions and the conductive clips forming an inductor; and a second layer of mold compound of different composition than the first layer and formed over the first layer of mold compound, the second layer of mold compound including a magnetic mold compound surrounding the conductor portions of the inductor.

### TECHNICAL FIELD

This disclosure relates generally to electronic packaging, and more particularly to packaging semiconductor devices and associated inductors in a microelectronic device package.

### BACKGROUND

The semiconductor industry is continually developing microelectronic device packages with more functionality by placing components in a single packaged device such as a module. By providing a semiconductor die or multiple semiconductor dies and by including the necessary passive components to form a commonly needed function in a single microelectronic device package assembly, users are freed from the necessity of determining the values and types of various passive components needed with a semiconductor die to perform these common functions. By integrating these devices into a single microelectronic package, the system board area needed to implement the commonly needed function is reduced. Examples microelectronic device packages include power supplies, power converters including AC-DC or DC-DC converters, voltage regulators, battery chargers, and power controllers. A power module may include a power semiconductor die, such as a switching power controller and a switching power transistor or pairs of switching power transistors, and/or may include a power transistor gate driver, along with various passive components such as capacitors, resistors, and inductors to form a complete power system.

The passive components used in these modules can include relatively large inductors or transformers. These components can be mounted near the semiconductor die on a circuit substrate, and traces on the circuit substrate can couple the devices together. One example application for an integrated passive component is an inductor which can be serially coupled between a switching node and an output configured for supplying current to a load, for example. A switching power semiconductor die can alternatively supply current to or sink current from the inductor using pulse width modulated signals to provide a power function, such as a regulated output voltage for supplying current to the load. The switching power semiconductor die can include power transistors for supplying current from a voltage supply and gate driver transistors for controlling the operation of the power transistors. By operating the power transistors using pulse frequency modulation or pulse width modulation to rapidly switch the power transistors on and off, a regulated voltage can be output using the inductor. Transformers can be formed from inductors coupled to multiple power semiconductor dies. Transformers can couple current across an isolation barrier, to provide current to a load that is electrically isolated from a power supply, for example, or to transfer data across an isolation barrier.

To assemble the semiconductor dies and the inductors in a module such as a microelectronic device package assembly, the semiconductor dies can be mounted to a package substrate. Molding operations can be performed to form a mold compound over the package substrate and to protect the semiconductor die and other devices. To improve performance of the inductors, magnetic mold compound can be used. However, the magnetic mold compound can negatively impact the reliability of a package including a power semiconductor die, as the magnetic mold compound includes metal spheres or particles placed in close proximity to one another in a dielectric, so that under high voltage conditions arcing or an unwanted current path can occur. Further, the magnetic mold compound is relatively expensive, about forty times the cost of conventional epoxy-resin electronic mold compound (“EMC”), so that use of the magnetic mold compound to form the body of the microelectronic device package and protect the devices can substantially increase the cost of the microelectronic device package. In some power semiconductor device applications, dielectric breakdown can negatively impact the magnetic mold compound, requiring additional package design constraints such as requiring a larger package volume, further increasing costs.

There is thus a continuing need for increasingly reliable and cost-effective assembly methods providing inductors together with the associated semiconductor dies in a robust microelectronic device package.

### SUMMARY

In a described example, a method includes: mounting a semiconductor die on a device side surface of a package substrate; mounting conductive clips configured for supporting conductor portions on the device side surface of the package substrate, the conductive clips spaced from the semiconductor die, the clips extending from the device side surface to a distal end and having a height that is greater than a thickness of the semiconductor die; forming a first layer of mold compound over the semiconductor die and the conductive clips, the distal ends of the conductive clips exposed on a surface of the first layer of mold compound; mounting conductor portions on the distal ends of the conductive clips to form an inductor, the conductor portions extending over and across the semiconductor die; and forming a second layer of mold compound of different composition than the first layer of mold compound over the first layer of mold compound, covering the conductor portions and the conductive clips, the second layer of mold compound comprising magnetic mold compound.

In another described example, an apparatus includes: at least one semiconductor die mounted to the device side surface of a package substrate; conductive clips mounted on the device side surface of the package substrate, the conductive clips spaced from the semiconductor die, the conducive clips extending from the device side surface to a distal end and having a height that is greater than a thickness of the semiconductor die; a first layer of mold compound over the device side surface of the package substrate, the first layer of mold compound covering the semiconductor die, while the distal ends of the conductive clips are exposed from the first layer of mold compound; conductor portions mounted on the distal ends of the conductive clips, the conductor portions extending over and across the semiconductor die, the conductor portions and the conductive clips forming an inductor; and a second layer of mold compound of different composition than the first layer of mold compound formed over the first layer of mold compound, the second layer of mold compound comprising a magnetic mold compound surrounding the conductor portions of the inductor.

In a further described example, a microelectronic assembly includes: a conductive leadframe; a semiconductor die mounted to a device side surface of the conductive leadframe; conductive clips configured to mount conductor portions, the conductive clips mounted to the device side surface of the conductive leadframe, the conductive clips positioned on opposite sides of the semiconductor die and extending away from the device side surface of the package substrate to distal ends; a first layer of mold compound covering the semiconductor die and the device side surface of the conductive leadframe, the conductive clips extending through the first layer of mold compound and the distal ends of the conductive clips exposed from the first layer of mold compound; at least two conductor portions mounted on the distal ends of the conductive clips, the conductor portions positioned over and extending across the semiconductor die and electrically coupled together to form an inductor that is coupled to the semiconductor die; and a second layer of mold compound of a different composition than the first layer of mold compound comprising magnetic mold compound over the first layer of mold compound and surrounding and covering the conductor portions of the inductor.

### BRIEF DESCRIPTION OF THE DRAWINGS

FIGS. 1A-1B are cross-sectional views of a multilayer package substrate and of a semiconductor die mounted to the multilayer package substrate, components useful in the arrangements.

FIGS. 2A-2B are perspective views of the components of FIGS. 1A-1B.

FIGS. 3A and 3B illustrate in two projection views a semiconductor wafer having semiconductor dies formed on it and configured for flip-chip mounting, and an individual semiconductor die for flip-chip mounting, respectively.

FIG. 4 illustrates in a cross-sectional view an example multilayer package substrate that can be used in an arrangement.

FIGS. 5A-5C illustrate, in a projection view, a plan view from a board side, and a partially transparent plan view, details of an enhanced quad flat no-lead (QFN) package that can be used in an arrangement.

FIG. 6A illustrates, in a cross-sectional view, an example arrangement with an inductor and a semiconductor die in a microelectronic device package. FIGS. 6B-6F illustrate, in a series of cross-sectional views, selected steps for forming the example arrangement of FIG. 6A. FIGS. 6G-6H illustrate, in two projection views, additional details of an alternative arrangement. FIG. 6I illustrates, in a cross-sectional view, alternative conductor portion shapes that can be used in additional example arrangements.

FIG. 7 illustrates in a flow diagram an example method for forming an arrangement.

### DETAILED DESCRIPTION

In the drawings, corresponding numerals and symbols generally refer to corresponding parts unless otherwise indicated. The drawings are not necessarily drawn to scale.

Elements are described herein as “coupled.” The term “coupled” includes elements that are directly connected and elements that are indirectly connected, and elements that are electrically connected even with intervening elements or wires are coupled.

The term “semiconductor die” is used herein. A semiconductor die can be a discrete semiconductor device such as a bipolar transistor, a few discrete devices such as a pair of power field effect transistor (“FET”) switches fabricated together on a single semiconductor die, or a semiconductor die can be an integrated circuit with multiple semiconductor devices such as the multiple capacitors in an A/D converter. The semiconductor die can include passive devices such as resistors, inductors, filters, sensors, or active devices such as transistors. The semiconductor die can be an integrated circuit with hundreds or thousands of transistors coupled to form a functional circuit, for example a microprocessor or memory device.

In an example application for an arrangement, a power semiconductor die can include power FETS configured as a high side driver and as a low side driver that can alternatively couple a switch node coupled between the power FETS to a positive power supply, or to a ground potential. By alternatively sourcing current or sinking current to and from an inductor coupled between the switch node and an output, current can be supplied to a load at the output while regulating the output voltage. The power FETS can be driven by rapidly switching pulse width modulated or pulse frequency modulated gate signals to control the voltage and/or current. Applications for switching power semiconductor dies include buck voltage converters, boost voltage converters, buck-boost voltage converters, battery chargers, DC power supplies for automotive applications, solar applications, electric vehicle applications, robotics, and power supplies. As appliances are increasingly made portable using battery power, the need for AC-DC converters and DC-DC converters is increasing, and as all circuit devices are made ever smaller, the need for integrated power function solutions including the semiconductor dies and associated components in a single microelectronic device package also increases.

The term “passive component” is used herein. A passive component is a component without a transistor device, examples include inductors, coils, transformers, capacitors, resistors, diodes, and sensors. For example, a passive component can be an inductor. Inductors useful in the arrangements can be two terminal inductors formed as conductor strips in magnetic mold compound positioned to extend over a semiconductor die. Other passive components including resistors, coils, inductors, diodes, and sensors can be formed as passive component dies and can be used in the arrangements. By providing the passive components needed to form a complete commonly needed function, users of the microelectronic device packages are freed from the need to provide mounting area on a system board for the passive components. Users are also freed from the need to determine values for the passive components needed to complete the function, that is, the microelectronic device package are modules that are increasingly integrated into systems.

In some arrangements, multiple semiconductor dies can be packaged together. For example, a power metal oxide semiconductor (MOS) field effect transistor (FET) (or MOSFET) semiconductor die, and a logic semiconductor die (such as a gate driver die, or a power FET controller die) can be packaged together. These integrated devices can be referred to as “multichip modules” or “system-in-package” (or “SIP”) devices. In example arrangements, at least one semiconductor die is mounted to a package substrate that provides conductive leads; a portion of the conductive leads form the terminals for the module or microelectronic device package. The semiconductor die can be flip chip mounted to the package substrate with a device side surface facing the substrate and a backside surface facing away from the circuit substrate. In flip chip semiconductor device packages, conductive post connects that extend from bond pads on the semiconductor die and which have solder deposited on a distal end couple conductive leads of the package substrate to bond pads on the semiconductor die. A thermoset epoxy resin mold compound can be applied to the semiconductor die in a molding process, or using epoxy, plastics, or resins that are liquid at room temperature and are subsequently cured. The mold compound may be formed in a mold using an encapsulation process. In an example process useful with the arrangements, film assisted molding can be used. Film is used with a vacuum in a mold tool to line the molds, making release of the molded components after processing easier, and assisting in controlling the dimensions of the exterior surfaces of the molded components. In other arrangements, the semiconductor die can be mounted to the package substrate with the device side surface facing away from the circuit substrate. In this arrangement, the semiconductor die can be coupled to the conductive leads of the package substrate by any appropriate method, such as wire bond, for example.

The term “package substrate” is used herein. A package substrate is a substrate arranged to receive a semiconductor die and to support the semiconductor die in a completed module or microelectronic device package. Package substrates useful with the arrangements include multilayer substrates. In example multilayer package substrates that are useful with the arrangements, build-up package substrates can be used. Multilayer package substrates can have trace level conductors spaced by dielectric material in layers, and vertical connection layers that extend through the dielectric material between trace level conductors, to form routing networks. Alternative package substrates that can be used include conductive leadframes, which can be formed from copper, aluminum, stainless steel, steel, and alloys such as Alloy 42 and copper alloys. The leadframes can include a die pad with a die side surface for mounting a semiconductor die, and conductive leads arranged near and spaced from the die pad for coupling to bond pads on the semiconductor die. In flip chip packages used in example arrangements, a conductive leadframe can be used in a “flip chip on lead” or “FCOL” package, where there is no dedicated die pad, instead the die is mounted to the leads of the leadframe using the conductive post connects. Semiconductor dies can be flip chip mounted to the leadframes using conductive post connects to couple the bond pads of the semiconductor die to conductive portions on the leadframe.

The term “build-up package substrate” is used herein. A build-up package substrate is a substrate that has multiple trace level conductor layers, and which has vertical connection layers extending through dielectric material between the trace level conductor layers. In an example arrangement, a build-up package substrate is formed in an additive manufacturing process by plating a patterned conductor level and then covering the conductor with a layer of film dielectric material. The film dielectric material can be applied at an elevated temperature to soften the film material, and a vacuum can be used to cause the film dielectric material to conform to the conductors underneath. The film dielectric material can then be thermally cured to harden the dielectric material. Multiple layers of the film dielectric material can be applied. Grinding can be performed on the dielectric material to expose portions of the layer of conductors. Additional plating layers can be formed to add additional levels of conductors, some of which are coupled to the prior trace level conductor layers by vertical connection layers, and additional film dielectric material can be deposited at each level and can cover the conductors. By using an additive or build up manufacturing approach, and by performing multiple plating steps, dielectric film lamination steps, and grinding steps, a build-up package substrate can be formed with an arbitrary number of conductor layers. In an example arrangement, copper conductors are formed by plating, and a thermoplastic material can be used as the dielectric material. In a particular example, the dielectric film used in a build-up package substrate can be an epoxy-based build-up film commercially available as “Ajinomoto Build-up Film,” or “ABF,” available from Ajinomoto Co., Inc., of Tokyo, Japan.

In packaging microelectronic and semiconductor devices, mold compound may be used to partially cover a package substrate, to cover components, to cover a semiconductor die, and to cover the electrical connections from the semiconductor die to the substrate. This molding process can be referred to as an “encapsulation” process, although some portions of the substrates are not covered in the mold compound during encapsulation, for example terminals and leads of the circuit substrate are exposed from the mold compound. Encapsulation is often a compressive molding process, where thermoset mold compound such as resin epoxy can be used. A room temperature solid or powder mold compound can be heated to a liquid state and then molding can be performed by pressing the liquid mold compound into a mold through runners or channels. Transfer molding can be used. Film assisted molding processes can be used to form an arrangement. Compression molding can be used, where the units to be covered with mold compound are pressed into a two-part mold with mold compound to force the mold compound to fill the mold. Unit molds shaped to surround an individual device may be used, or block molding may be used, to form multiple packages simultaneously for several devices from mold compound. The devices to be molded can be provided in an array or matrix of several, hundreds or even thousands of devices in rows and columns that are then molded together. When mold compound is formed over the components mounted to a device mounting surface of a circuit substrate, it may be referred to as an “overmolding” process. In an example application, a film assisted molding process can use release films placed in a mold to control the molding process, to form exterior surfaces at precise points, so that some components are exposed from the completed molded layer at a surface.

After the molding, the individual packaged devices are cut from each other in a sawing operation by cutting through the mold compound and circuit substrate in saw streets formed between the devices. Portions of the circuit substrate leads are exposed from the mold compound package to form terminals for the microelectronic device packages.

The term “scribe lane” is used herein. A scribe lane is a portion of semiconductor wafer between semiconductor dies. Sometimes in related literature the term “scribe street” or “scribe line” is used. Once semiconductor processing is finished and the semiconductor devices are complete, the semiconductor devices are separated into individual semiconductor dies by severing the semiconductor wafer along the scribe lanes. The separated dies can then be removed and handled individually for further processing. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “saw street” is used herein. A saw street is an area between molded electronic devices used to allow a saw, such as a mechanical blade, laser, or other cutting tool to pass between the molded electronic devices to separate the devices from one another. This process is another form of singulation. When the molded electronic devices are provided in a strip with one device adjacent to another device along the strip, the saw streets are parallel and normal to the length of the strip. When the molded electronic devices are provided in an array of devices in rows and columns, the saw streets include two groups of parallel saw streets, the two groups are normal to each other, and the saw will traverse the molded electronic devices in two different directions to cut apart the packaged electronic devices from one another in the array.

The term “inductor” is used herein. An inductor is a conductive element arranged to carry current from a first terminal to a second terminal and can be used to provide inductance. The inductors of example arrangements are formed of conductive clips supporting conductor portions described as “staple” shaped, “C” shaped, and as “ladder” shaped. The conductor portions of the inductors in example arrangements have two ends that are configured for mounting to the conductive clips and an inductor includes at least one conductor portion segment between the two ends that extends from one end to the other. In the arrangements, the inductor can include one or more conductor portions that are strips that extend above and across a semiconductor die. The conductor portion between the two ends is open, while the segment across the semiconductor die can be elevated above the semiconductor die, the inductor having an opening facing the semiconductor die in one example like a staple with two legs, or in an open shape like the letter “C” with two feet at the ends. In another example the inductor can have an additional conductor portion extending over the semiconductor die in the opening and the conductor portions then can form a “ladder” shape in a cross-sectional view. Other shapes such as a “U” shape can be used. Multiple segments of conductor portions can be used that are coupled together with additional pairs of conductive clips for increased inductance in the inductor.

In example arrangements, a semiconductor die is mounted to a package substrate. In certain arrangements, the semiconductor die is flip chip mounted, with electrical connections between the semiconductor die and the package substrate made by conductive post connects extending from the semiconductor die. In alternative arrangements, the semiconductor die is mounted face up on the package substrate, and wire bonding is used to form electrical connections between the semiconductor die and the package substrate. Clips arranged for receiving the ends of a conductor portion for an inductor are placed on the package substrate on two sides of the semiconductor die. A first molding process forms an electronic mold compound layer over the semiconductor die, while the distal ends of the clips extend away from the package substrate and are exposed from the layer of electronic mold compound. A conductor portion for an inductor is mounted on the clips, one or multiple conductor portions can be used to form an inductor, the conductor portions extending over the semiconductor die so that the area used by the inductor is similar to the area of the semiconductor die, keeping the overall package size for the combined components relatively small.

A second molding process forms a layer of magnetic mold compound over the layer of electronic mold compound, encapsulating the conductor portions of the inductor and covering the inductor and the layer of electronic mold compound. The magnetic mold compound is isolated from the semiconductor die and the package substrate by the first layer of mold compound. The package substrate can be a multilayer package substrate such as a build-up substrate, or a copper leadframe, including a flip chip on lead (FCOL) leadframe. In a particular example, the microelectronic device package formed is a type of enhanced quad flat no-lead package commercially available from Texas Instruments Incorporated, the assignee of this disclosure, and sold under the trademark HotRod™. HotRod™ packages feature large power rails that extend across or partially across the body of the package on a board side surface, providing a low resistance path for power and ground signals, and providing a thermal dissipation path for the semiconductor die that is flip chip mounted directly to the leadframe and is thermally coupled to the rails. Other package substrates can be used in the arrangements. Wire bonded semiconductor dies on die pads of leadframes can be used to form additional arrangements.

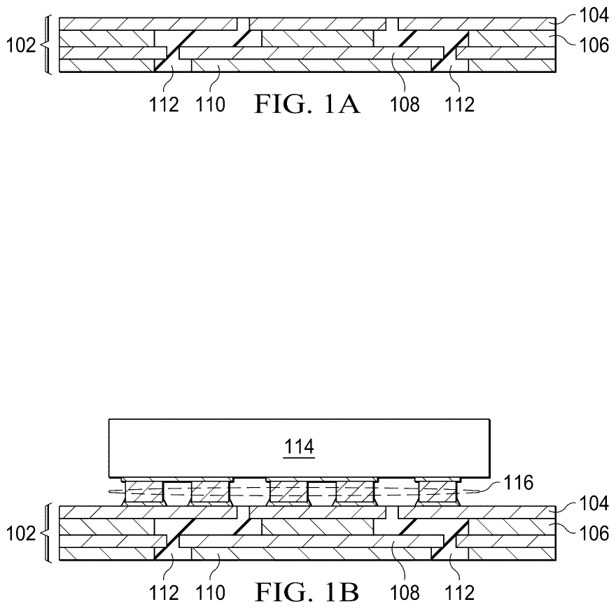

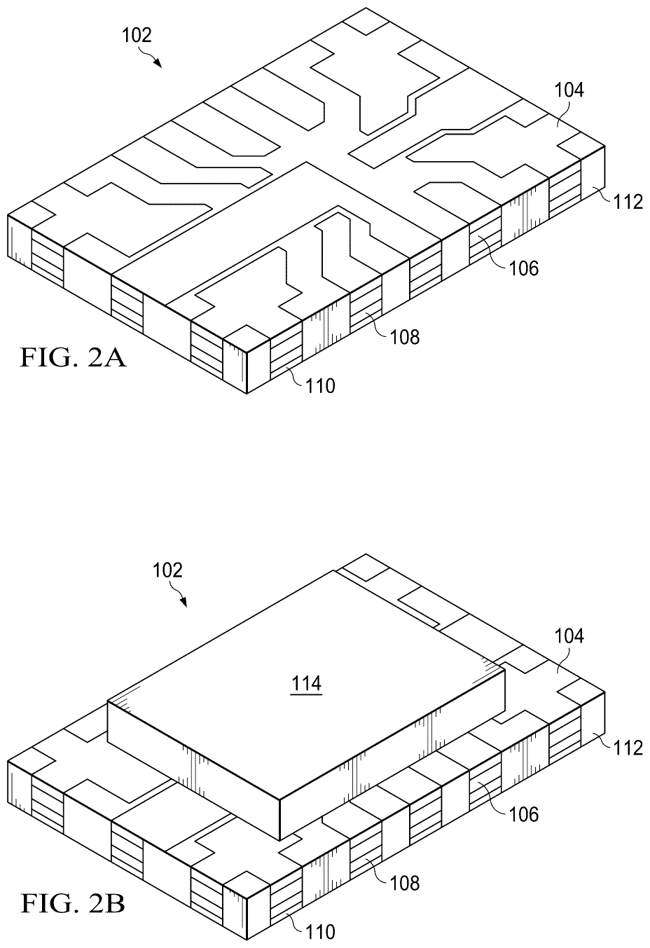

FIGS. 1A-1B are cross-sectional drawings illustrating an example multilayer package substrate, and a semiconductor die flip chip mounted to the package substrate. FIGS. 2A-B are perspective diagrams of the components illustrated in FIGS. 1A-1B.

In FIG. 1A, an example package substrate 102 includes four layers: first layer 104, second layer 106, third layer 108, and fourth layer 110. Each of these layers can have a patterned conductive layer comprising copper, silver, titanium, gold, or other conductive materials, including alloys of these conductive materials. In this example package substrate 102, layer 110 is on the board side of the package substrate 102, and portions of layer 110 are shaped to form terminals for a microelectronic device package. Layer 104 is on the device mounting surface of package substrate 102, and portions of this layer are arranged to form conductive lands for receiving a flip-chip mounted semiconductor die. The portion of each conductive layer 104, 106, 108, 110 that does not include conductive material is filled with dielectric material such as dielectric 112. The dielectric material 112 of package substrate 102 can be a thermoplastic or a thermoset material.

In a process useful with the arrangements, package substrate 102 can be a build-up package substrate. Build-up package substrates can be formed in an additive manufacturing process by first using sputter deposition to deposit a seed layer on a carrier or film, then masking the seed layer, subsequently plating a conductor layer on the seed layer, then removing unwanted portions of the seed layer, and then using an epoxy film to form the dielectric material over the conductor layer. This process can be performed repeatedly to form laminated layers. An example film used in forming build-up substrates is Ajinomoto Build-Up Film (ABF). By using an additive process to form the build-up package substrate in layers, and in contrast to laminated substrates formed with filled vias between trace layers, arbitrary conductor shapes can be formed including rails or other rectangular shapes as vertical connection layers between the trace level conductors. By forming conductor shapes that extend vertically using the ABF build-up process, the conductors can be stacked to form columns, blocks, or conductive rails of various thicknesses to form low resistance paths between devices on the device side surface of the circuit substrate and terminals on a board side surface. Alternative dielectric materials include thermoplastics such as ASA (Acrylonitrile Styrene Acrylate), thermoset mold compound, and other dielectric materials including epoxy resin, epoxies, resins, or plastics. A perspective view of package substrate 102 is shown in FIG. 2A.

FIG. 1B shows an example where a semiconductor die 114 is flip chip mounted on package substrate 102. Semiconductor die 114 includes conductive post connects 116. Conductive post connects 116 can be formed on bond pads on a device side surface of semiconductor die 114. A solder bump (not shown in this figure) can be formed on top of each of the distal ends of the conductive post connects. The semiconductor die 114 is then flipped over so that the device side surface faces the device mounting surface of the package substrate, and the semiconductor die positioned so that the solder bumps contact pads in layer 104. Compression, heat, or vibration is used to form a conductive connection from layer 104 to conductive post connects 116 via the solder bumps. Thermal reflow processes can be used to form a solder joint to the conductive post connects. A perspective view of semiconductor die 114 mounted on package substrate 102 is shown in FIG. 2B.

FIGS. 1A-1B and 2A-2B illustrate certain details of flip chip semiconductor die mounts using package substrates. Not shown in FIGS. 1A-1B and 2A-2B but also often present are additional components such as capacitors, resistors, coils, or inductors that can be mounted with the semiconductor dies to form a module or to form microelectronic assemblies.

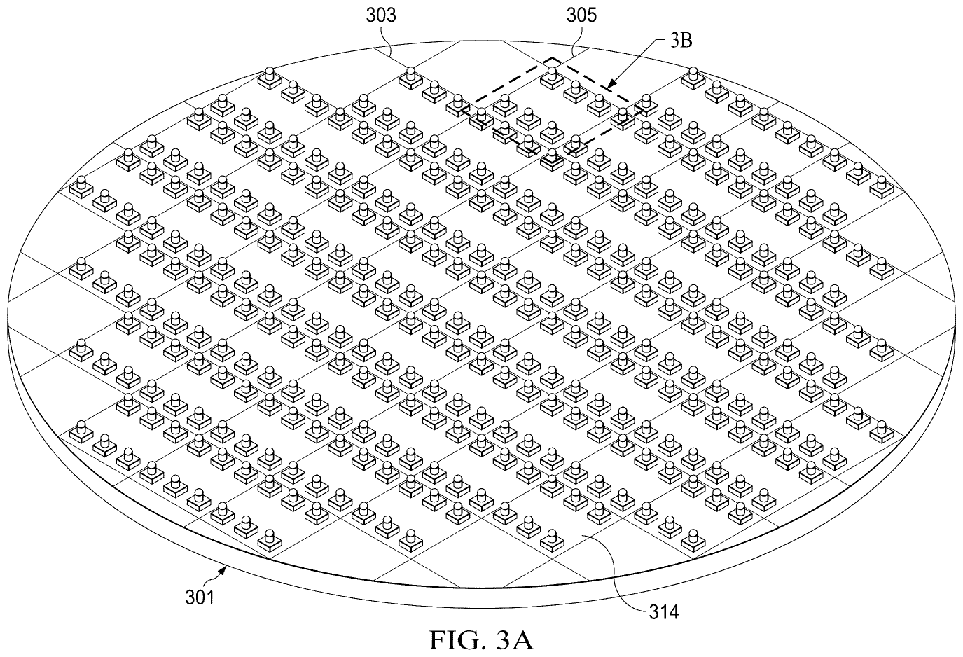

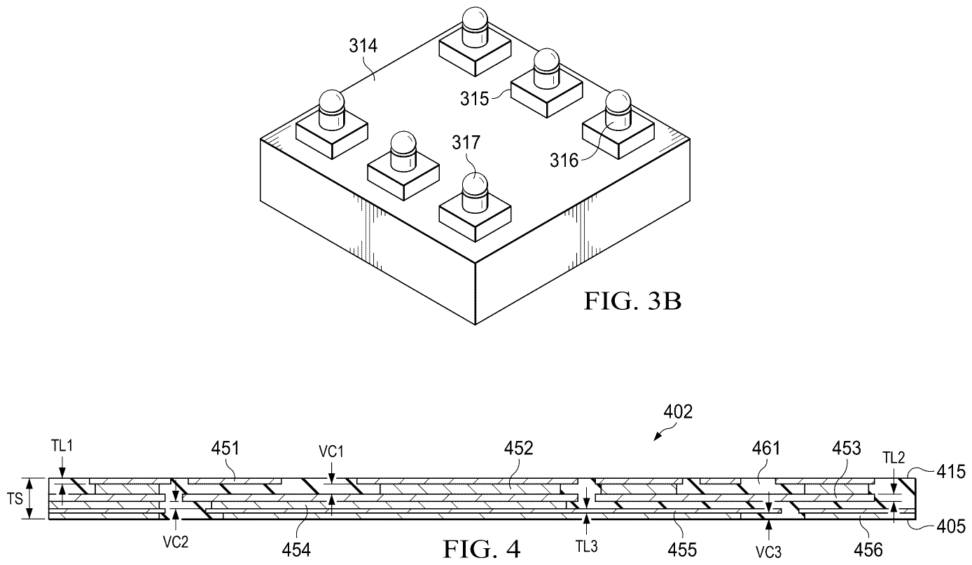

FIGS. 3A and 3B illustrate in two projection views a semiconductor wafer having semiconductor dies formed on it that are configured for flip chip mounting, and an individual semiconductor die configured for flip chip mounting, respectively. In the arrangements, a semiconductor die ready for mounting can be formed using wafer bumping. In wafer bumping, after the semiconductor devices in the semiconductor substrate are completed as individual dies in a semiconductor manufacturing process, conductive post connects extending from bond pads on the semiconductor dies can be formed by a plating process. Solder can be deposited or formed on the distal ends of the conductive post connects. Various conductor materials can be used such as copper, gold, and aluminum. Copper is often used. When the conductive post connects are of copper, the term “copper pillar” is often used. When solder is applied to the distal end and then shaped as a bump shape in a thermal reflow process, the conductive post connects can be described as “copper pillar bumps.” Solder balls can also be used.

In FIG. 3A, an example semiconductor wafer 301 is shown with an array of semiconductor dies 314 formed in rows and columns on a surface. The semiconductor dies 314 can be formed using processes in a semiconductor manufacturing facility including ion implantation, doping, anneals, oxidation, dielectric and metal deposition, photolithography, pattern, etch, photoresist stripping, chemical mechanical polishing (CMP), electroplating, and other processes for making semiconductor devices. Scribe lanes 303 and 305, which are perpendicular to one another, and which run in parallel groups across the semiconductor wafer 301, separate the rows and columns of the completed semiconductor dies 314, and provide defined areas for dicing the wafer 301 in a singulation operation, to separate the semiconductor dies 314 from one another.

FIG. 3B illustrates a single semiconductor die 314, with bond pads 315, which are conductive pads that are electrically coupled to devices (not shown) including transistors and circuitry formed in the semiconductor die 314. Conductive post connects 316 are shown extending away from a proximate end mounted on the bond pads 315 on the surface of semiconductor die 314 to a distal end, and solder bumps 317 are formed on the distal ends of the conductive post connects 316. The conductive post connects 316 can be formed by electroless plating or by electroplating. In an example, the conductive post connects 316 are copper pillar bumps. Copper pillar bumps can be formed by sputtering a seed layer over the surface of the semiconductor wafer 301, forming a photoresist layer over the seed layer, using photolithography to expose the bond pads 315 in openings in the layer of photoresist, plating the copper conductive post connects 316 on the bond pads, and plating a lead solder or a lead-free solder such as an tin, silver (SnAg) or tin, silver, copper (SnAgCu) or “SAC” solder to form solder bumps 317 on the distal ends of the copper conductive post connects 316. In an alternative approach, solder bumps or particles may be dropped onto the distal ends of the copper post connects and then reflowed in a thermal process to form solder bumps. Other conductive materials can be used for the conductive post connects in electroplating or electroless plating operation, including gold, silver, nickel, palladium, or tin, for example. Not shown for clarity of illustration are under bump metallization (UBM) portions which can be formed over the bond pads to improve plating and adhesion between the conductive post connects 316 and the bond pads 315. After the plating operations, the photoresist is then stripped, and the excess seed layer is etched from the surface of the wafer 301. The semiconductor dies 314 are then separated by dicing, or are singulated, using the scribe lanes 303, 305 (see FIG. 3A).

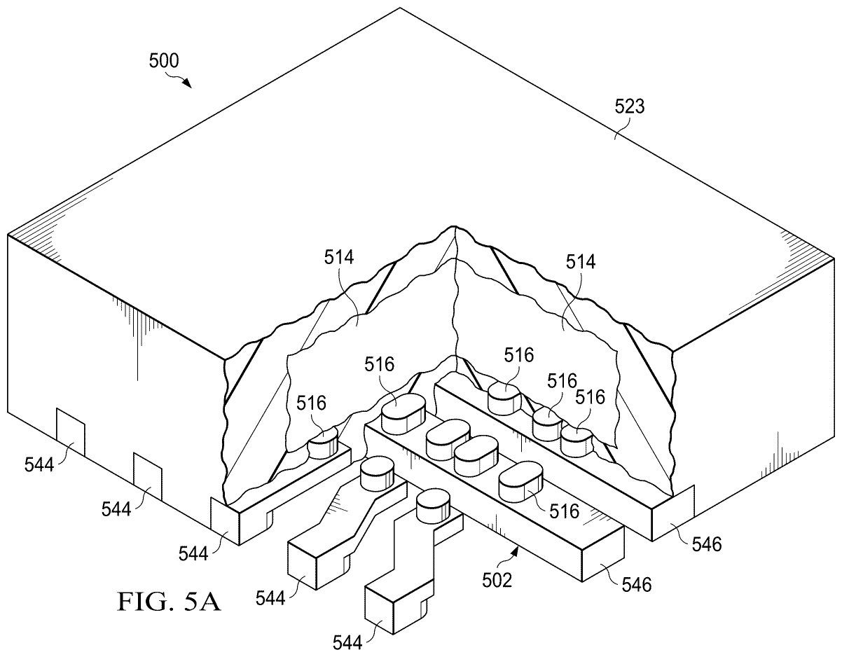

FIG. 4 illustrates in a cross-sectional view another multilayer package substrate 404 that can be used with the arrangements. In FIG. 4, the multilayer package substrate 404 has a device side surface 415 and a board side surface 405. Three trace level conductor layers 451, 453, 455 are formed spaced from one another by dielectric material 461, the trace level conductor layers are patterned for making horizontal connections, and three vertical connection layers 452, 454, 456 form electrical connections between the three trace level conductor layers 451, 453, 455 and extend through the dielectric material 461 that is disposed over and between the trace level conductor layers. The dielectric material 461 can be a build-up dielectric film such as ABF, another thermoplastic material such ASA, or can be a thermoset material, such as epoxy resin mold compound.

The package substrates can have various thicknesses. In one example the multilayer package substrate 404 has a substrate thickness labeled “TS” of about 200 μm. The various trace level conductor layers and dielectric layers between the trace level conductor layers, including the vertical connection layers, can have varying thickness as well. These thicknesses taken together can add up in total to the substrate thickness TS. In a particular example of a multilayer package substrate useful with the arrangements, the first trace level conductor layer, 451, near the device side surface 415 of the multilayer circuit substrate, can have a trace level conductor layer thickness TL1 of 15 μm. The first vertical connection layer, 452, can have a thickness VC1 of 25 μm. The second trace level conductor layer, 453, sometimes coupled to the first trace level conductor layer 451 by the first vertical connection layer 452, can have a thickness labeled TL2 of 60 μm. The second vertical connection layer, 454, can have a thickness labeled VC2 of 65 μm. The third trace level conductor layer, 455, can have a thickness labeled TL3 of 15 μm, and the third vertical connection layer, 456, can have a thickness labeled VC3 of 25 μm. Additional layers, such as conductive lands on the device side surface 415, or terminals on the board side surface 405, may be formed by plating (not shown in FIG. 4). A continuous vertical connection between the device side surface 415 and the board side surface 405 can be formed by patterning a stack of the trace level conductor layers and the corresponding vertical connection layers to form a continuous conductive path extending vertically through the dielectric material 461.

Note that in this description, the vertical connection layers 452, 454, and 456 are not described as “vias.” This is intentionally done in this description to distinguish the vertical connection layers of the build-up multilayer package substrate of the arrangements from the via connections of PCBs or other substrates, which are filled holes. The vertical connections of the arrangements can be formed using additive manufacturing, while in contrast, the vias in PCBs are usually formed by removing material, for example by via holes that are drilled into the substrate. These via holes between conductor layers then must be plated and filled with a conductor, which requires additional plating steps after the drilling steps. These additional process steps are precise manufacturing processes that add costs and require additional manufacturing tools and capabilities.

In contrast to conventional vias, the vertical connection layers used in the build-up process to form multilayer package substrates of the arrangements are formed in the same plating processes as those used in forming the trace level conductor layers, simplifying manufacture, and reducing costs. In addition, the vertical connection layers in the arrangements can be arbitrary shapes, such as rails, columns, or posts, and the rails can be formed in continuous patterns to form electric shields, tubs, or tanks, and can be coupled to grounds or other potentials, isolating regions of the multilayer circuit substrate from one another.

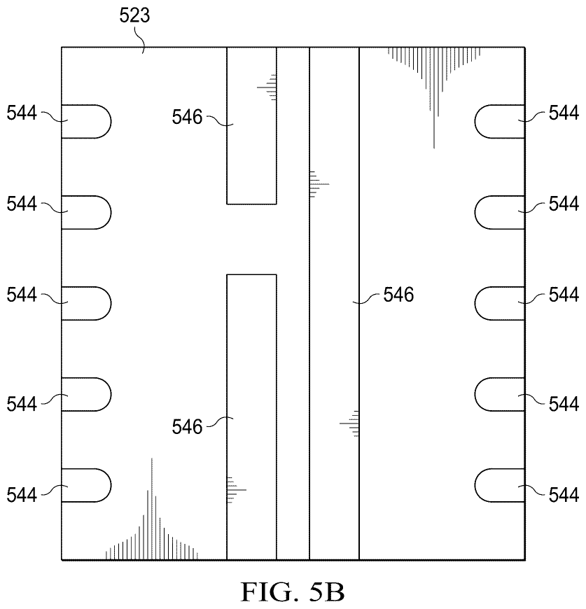

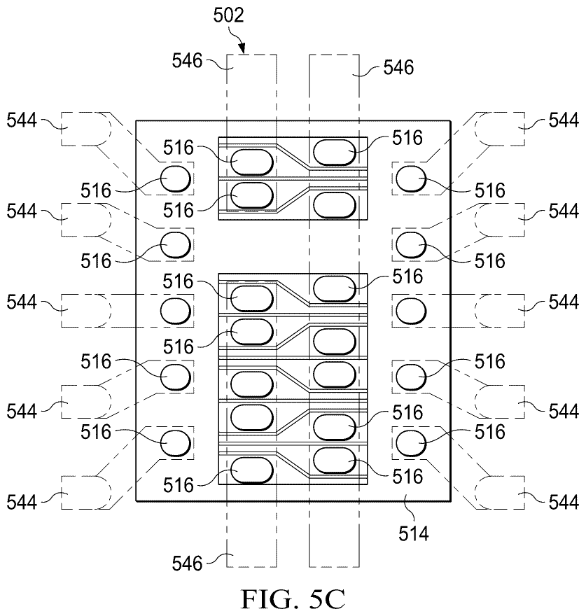

FIGS. 5A-5C illustrate, in a projection view from the top side, a plan view from a board side, and a partially transparent plan view of certain details, features of an enhanced quad flat no-lead HotRod™ package commercially available from Texas Instruments Incorporated, which can be used with the arrangements.

In FIG. 5A, the example microelectronics device package 500 is shown in a projection view from a top side, with mold compound 523, semiconductor die 514, package substrate 502, which in this illustrated example can be a copper or copper alloy leadframe, terminals 544 and power or ground rails 546. The terminals 544, which are configured for use as input-output terminals, are exposed portions of conductive leads of the leadframe (package substrate 502). The leadframe has conductive leads that are coupled to the semiconductor die 514 by solder joints and conductive post connects that extend from bond pads on the semiconductor die 514, which is flip-chip mounted on the leads of package substrate 502 (bond pads and post connects are not visible in FIG. 5A). Terminals 546 are conductive rails configured for carrying power supply voltage or ground potentials and are exposed on the board side from the mold compound 523, and these terminals are also coupled to the semiconductor die 514 by conductive pillars or pads formed on the semiconductor die 514.

FIG. 5B illustrates, in a plan view from a board side, additional features of the package 500 of FIG. 5A. Terminals 544, configured for input-output signals, and power rails 546, are shown exposed from mold compound 523. Power rails 546 provide both a low resistance path for relatively high current, such as is carried by a power supply connection or a ground connection, and a thermal dissipation path for the components in the microelectronic device package 500.

In FIG. 5C, additional details of package 500 are shown in a bottom view of the leadframe (package substrate 502), with the leadframe shown as partially transparent. Terminals 544 and rails 546 are formed from portions of the conductive leads of the leadframe, and the semiconductor die 514 is shown flip-chip mounted on the leads 512 with conductive post connects 516. The semiconductor die 514 is mounted to power rails and ground rails 546 using conductive pads that directly connect to corresponding traces on the semiconductor die.

The example package substrates and packages shown in FIGS. 1A-1B, 2A-2B, 4 and 5A-5C and described above can be used, in example arrangements, to mount both a semiconductor die (or multiple semiconductor dies) and an inductor having conductor portions that are positioned above and extend across the semiconductor die, to provide the inductor within a microelectronic device package. By positioning the conductors for the inductors above the semiconductor die, the arrangements provide an integrated device package without substantially increasing the total package area over the area of the semiconductor die. Further, in the example arrangements, two types of mold compound are used, the package substrate and the semiconductor die are positioned and then covered with conventional resin epoxy electronic mold compound (EMC) in a first layer. The inductor or inductors are formed with conductor portions that are then mounted on the distal ends of conductive clips mounted on the package substrate. the clips extend through the first layer of mold compound, and the conductor portions of the inductors are subsequently covered with a second layer of mold compound, in the arrangements the second layer of mold compound is a magnetic mold compound (“MMC”), which increases the inductance obtained. Because the magnetic mold compound is many times more expensive than conventional EMC, using both types of mold compound in the arrangements reduces the amount of MMC used, and reduces overall costs of the microelectronic device package (when compared to a package where magnetic mold compound is used alone to form the package body). Further, by isolating the magnetic mold compound from the package substrate and from the semiconductor die, problems that sometimes occur when using magnetic mold compound with high voltage potentials are eliminated, as the magnetic mold compound (which includes conductive metal filler particles that are positioned close together, sometimes allowing arcing or unwanted current flow to occur under high voltage) is isolated from these signals by the conventional mold compound, which has a higher dielectric breakdown characteristic, preventing arcing from occurring. Magnetic mold compound is commercially available from Resonac Corporation of Tokyo Japan, for example, and a group of mold compound products that are useful with the arrangements are referred to as “Resonac's Magnetic Molding Compound CEL-M.” The magnetic mold compound can be a thermosetting material with magnetic particles in the material and is produced for use in forming inductors.

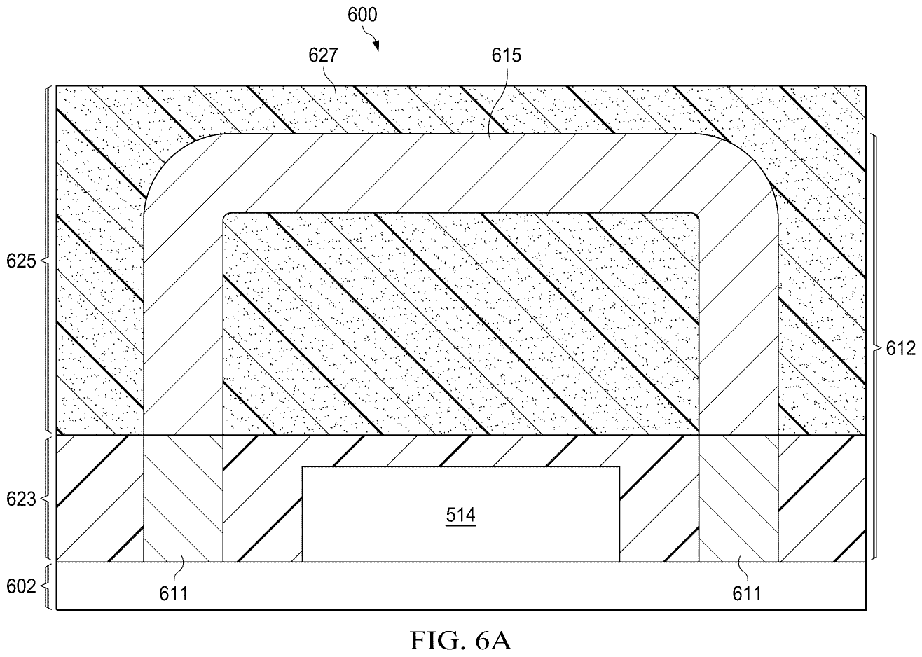

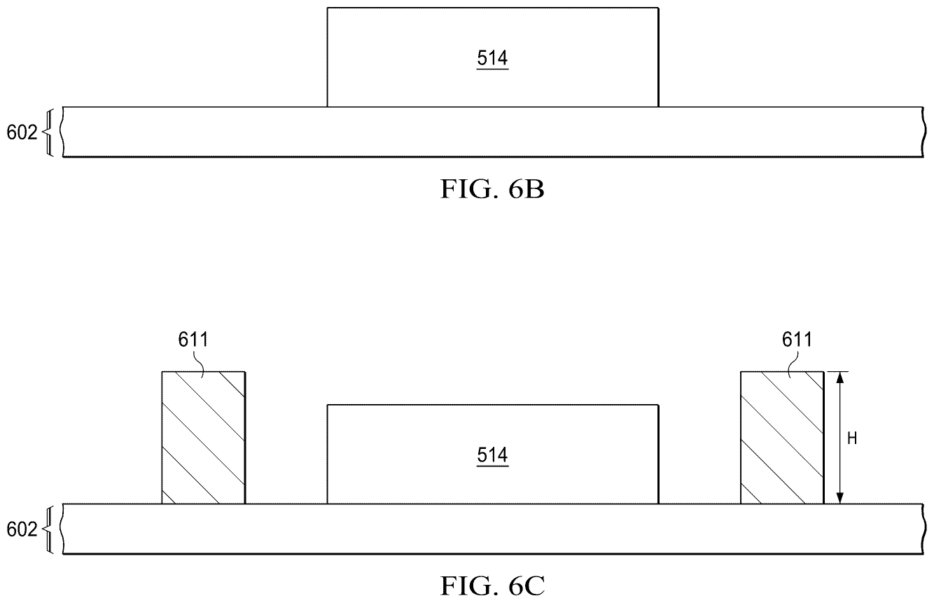

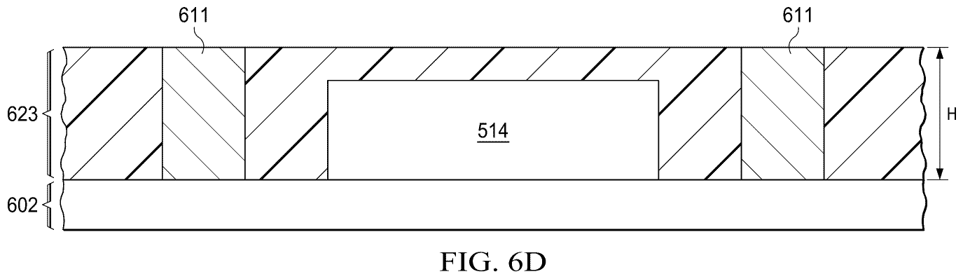

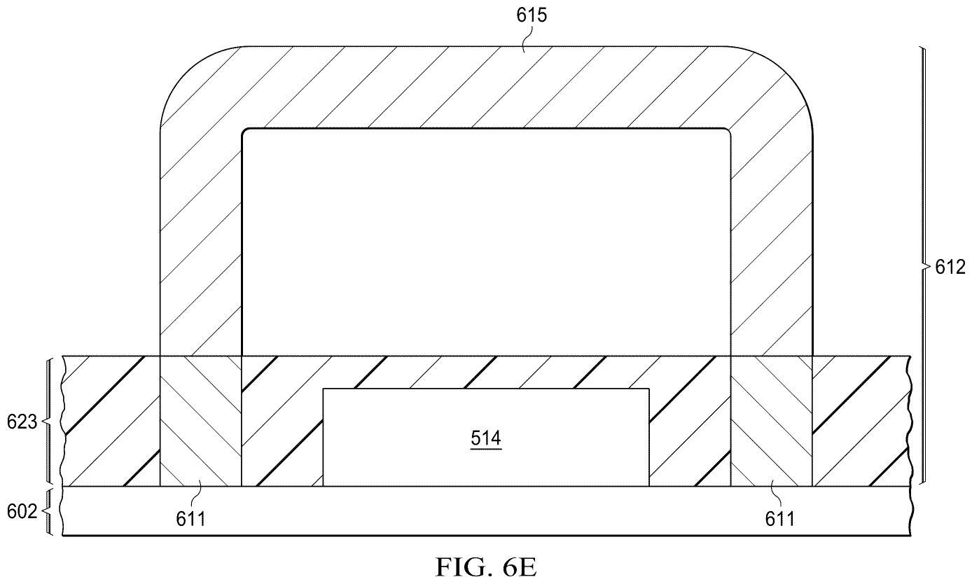

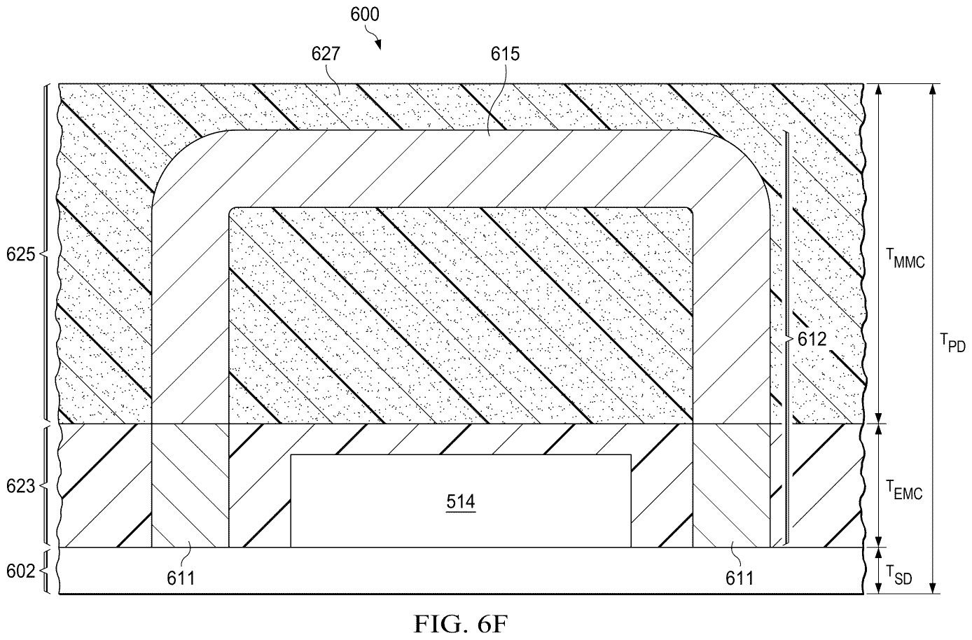

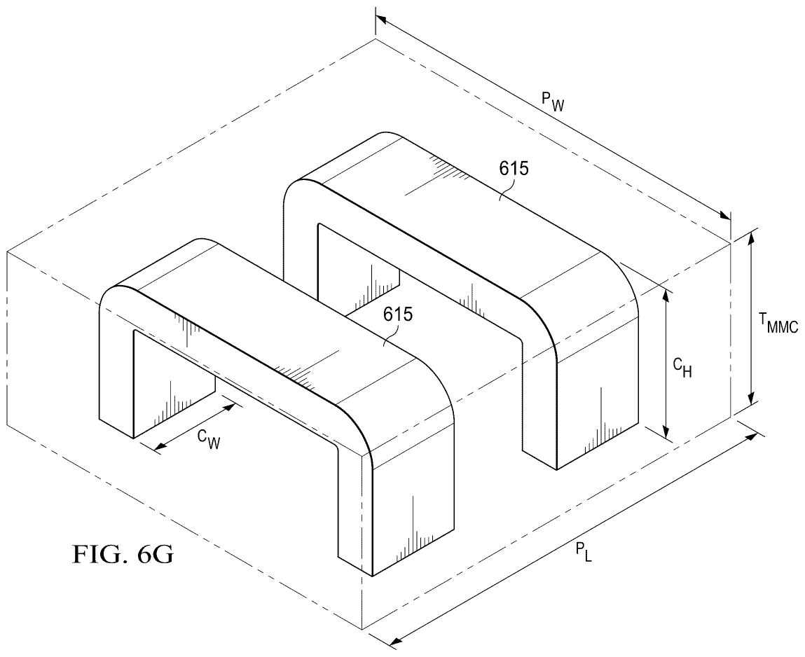

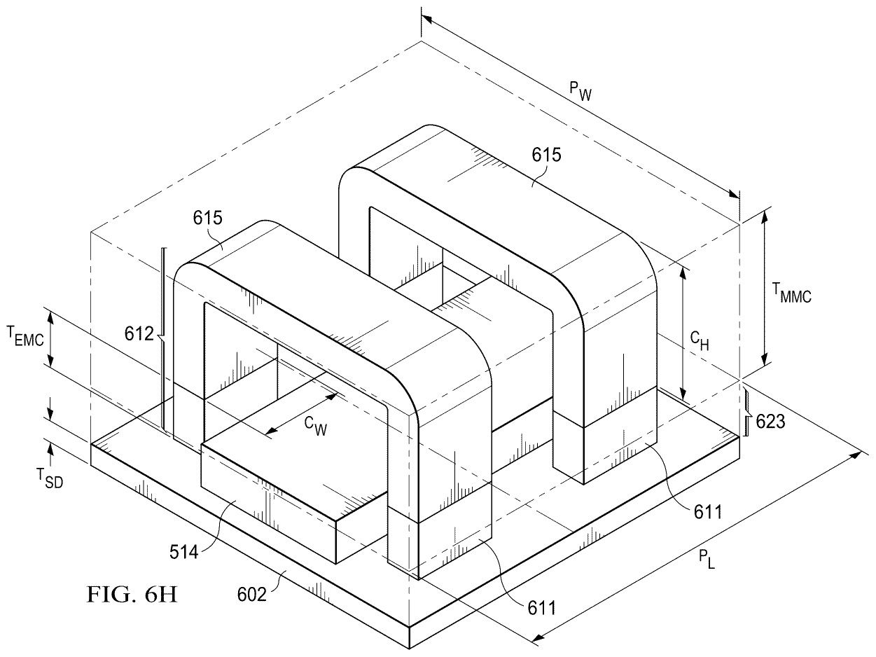

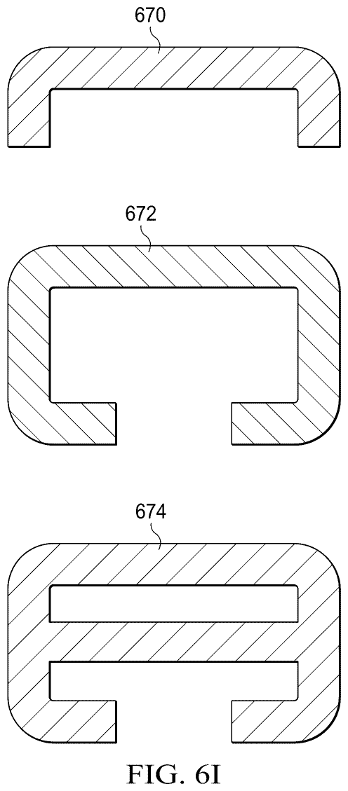

FIG. 6A illustrates, in a cross-sectional view, an example arrangement in a microelectronic device package 600. In FIG. 6A, package substrate 602 is shown, which can be a conductive leadframe. In a particular example arrangement, the package substrate 602 can be a HotRod™ leadframe similar to leadframe (package substrate 502) in FIG. 5A. Semiconductor die 514 is shown mounted on the leadframe (package substrate 602) in a flip chip configuration. In an alternative arrangement using a leadframe with a die pad as a package substrate, the semiconductor die could be mounted face up, with a device side surface facing away from the package substrate, and wire bonding could be used to form electrical connections to leads of the package substrate. In FIG. 6A, a first layer of mold compound 623 is shown over semiconductor die 514 and the device side surface of the package substrate 602. In this example the first layer of mold compound 623 can be EMC. Conductive clips 611 are shown mounted to the device side of the package substrate and provide both electrical connections and mechanical support for the conductor portion 615 of an inductor 612 which includes the clips 611. In the illustrated example pairs of conductive clips 611 are shown. However, in additional arrangements, additional conductive clips can be used, for example the conductive clips can be provided as smaller clips mounted to the package substrate in more numbers, also in another arrangement the conductor portion could have three or four legs, and additional conductive clips would be used to provide the support for the conductor portion 615. The conductor portion 615, which is shown in the cross section, is implemented as a U shaped or a staple shaped conductor portion mounted to clips 611 to form an inductor 612. In an example process, solder is used to mount the conductor portion 615 to the clips 611. Magnetic mold compound (MMC) 625 is shown formed in a second layer of mold compound over the first layer of mold compound 623 and surrounds the conductor portion 615 of inductor 612 with magnetic material. Magnetic mold compound 625 includes metal filler particles 627 that are coated with an insulating material. The use of the MMC 625 increases the inductance obtained by use of the inductor 612 (when compared to the inductance obtained by a similar conductor portion formed without use of the MMC 625).

In the example arrangements, the package substrate 602 and the semiconductor die 514 are advantageously isolated from the magnetic mold compound 625. The cross-sectional view of FIG. 6A shows a single conductor portion 615 used for inductor 612, however in an example application multiple conductor portions are formed and coupled to form an inductor for the application, such as a switching power converter. The semiconductor die 514 can be a switching power device that supplies current into, or sinks current from, the inductor that is coupled between the semiconductor die and an output terminal where a load receives the current. In an example application, a regulated output voltage can be maintained by use of a feedback control mechanism in the semiconductor die, the output voltage can be monitored and used to control the switching power device to regulate the output voltage.

The magnetic mold compound 625 can include filler particles 627 that are metal spheres or particles with an insulator coating suspended in a dielectric, such as resin or epoxy resin. Use of the magnetic mold compound to surround the conductor portion 615 increases the inductance obtained in the device package without an increase in package size (when compared to an inductor formed without use of the magnetic mold compound). In the arrangements, the magnetic mold compound 625 is used in a vertical arrangement in conjunction with conventional electronic mold compound for the first mold compound layer 623, reducing the amount of magnetic mold compound needed, which reduces package costs, as the magnetic mold compound 625 may be up to 40 times more expensive than the mold compound 623.

FIGS. 6B-6F illustrate, in a series of cross-sectional views, selected steps used to form the example arrangement of FIG. 6A. In FIG. 6B, the package substrate 602, which can be a leadframe similar to the leadframe 502 in FIG. 5A, is shown after a flip chip mounting step mounts the semiconductor die 514 to a device side surface. Not shown for clarity of illustration, but present, are conductive post connects extending from the device side surface of the semiconductor die 514, which faces downward as the elements are oriented in FIG. 6B. The conductive post connects connect to conductive leads on the package substrate 602 by solder (see, for example, the flip chip arrangement for semiconductor die 114 in FIG. 1B, which has post connects 116 and package substrate 102.) In an example process, solder disposed on the distal ends of the conductive pillar bumps is positioned in contact with the leads of the leadframe, and a thermal solder reflow step is used to form solder joints between the conductive post connects, which can be copper pillars, and the conductive leads of the package substrate 602.

In FIG. 6C, the elements of FIG. 6B are shown after an additional mounting step mounts the conductive clips 611 to the device side surface of the package substrate 602. In one process useful with the arrangements, the clips can be provided in a manner compatible with “pick and place” assembly tools and with surface mount technology (“SMT”), by providing the clips 611 on a tape and reel dispenser. The clips 611 are positioned, one pair of clips 611 for each conductor portion of an inductor to be mounted, on opposing sides of the semiconductor die 514, and in contact with traces on the package substrate 602, so that the inductor to be mounted on the clips is also electrically connected to traces on the package substrate 602. The clips 611 extend vertically (as the elements are oriented in FIG. 6C) from the package substrate 602 and have distal ends placed above the upper surface (again, as the elements are oriented in the figure) of the semiconductor die 514. In an aspect of the arrangements, the clips 611 have a height “H” in FIG. 6C that is greater than the thickness of the semiconductor die 514. This ensures that after a subsequent molding step, the distal ends of the clips 611 will be exposed from the first layer of mold compound, while at the same time, the semiconductor die 514 will be covered by the first layer of mold compound.

In FIG. 6D, the elements of FIG. 6C are shown after a first molding step. A first layer of mold compound 623, which can be an electronic mold compound (EMC) of epoxy resin, an epoxy, a resin, or a thermoplastic, is formed and covers semiconductor die 514 and the device side surface of the package substrate 602. The molding process can be a film assisted molding process, where a release film is used with transfer molds to control the thickness of the mold compound 623 so that the distal ends of the clips 611 are exposed from the mold compound 623 on an upper surface. In an alternative approach, mold compound 623 can be overmolded, covering clips 611, and after being cured, can be processed in a grinding process to expose the ends of the clips 611. The semiconductor die 514 is covered by mold compound 623, in part because the height “H” of the clips 611, and the corresponding thickness of the first layer of mold compound 623, is greater than the thickness of the semiconductor die 514.

In FIG. 6E, the elements of FIG. 6D are shown after a conductor portion 615 of an inductor 612 is mounted on clips 611, the inductor 612 includes the clips 611 and the conductor portion 615. In one example process, clips 611 are provided presoldered; in this approach prior to the clip mounting step shown in FIG. 6C, the clips 611 have solder deposited on the distal ends. In another alternative process that is useful with the arrangements, solder can be placed on the exposed ends of the clips 611 after the first molding process forms mold compound 623. Sputter or stencil techniques can be used to dispense the solder onto the ends of the clips 611. After the solder is present either by presoldering or by dispensing it, the conductor portion 615 can be mounted on clips 611. A thermal solder reflow process can be used to form a solder joint between the ends of clips 611 and the conductor portion 615. Note that while the cross-sectional views presented in FIGS. 6A-6D show a single conductor portion, in an example application two or more conductor portions are mounted to corresponding clips and coupled to form an inductor. (See, for example, s conductor portions 615 illustrated in the projection views of FIG. 6G and FIG. 6H).

FIG. 6F illustrates in another cross section the completed microelectronic device package 600 of the example arrangement, which is formed after an additional molding process step applies the second layer of mold compound, a magnetic mold compound layer 625, to the elements of FIG. 6E. Again, a film assisted molding process can be used. Note that FIG. 6F repeats the elements of FIG. 6A but in FIG. 6F microelectronic device package 600 is shown in additional detail, with certain layer thicknesses shown. In FIG. 6F, the microelectronic device package 600 has a total package thickness labeled “T_{PD}.” The package substrate 602, which can be a copper leadframe, such as a HotRod™ leadframe, a multiplayer package substrate or a build-up package substrate, has a thickness labeled “T_{SD}.” The first layer of mold compound 623, which can be an epoxy resin electronic mold compound (EMC), has a thickness labeled “T_{EMC}.” The second layer of mold compound 625, which can be a magnetic mold compound (MMC), has a thickness labeled “T_{MMC}.” In an example microelectronic device package formed including the arrangements, the total package thickness T_{PD} was about 4.2 millimeters. The total package thickness T_{PD} is the sum of the package substrate thickness T_{SD}, the first mold compound layer thickness T_{EMC}, and the second mold compound layer thickness T_{MMC}. In the example arrangement, the package substrate 602 was a copper leadframe with a thickness of about 0.2 millimeters. The first mold compound layer 623 had a thickness T_{EMC} in a range of about 0.45-0.80 millimeters. The second mold compound layer 625, the magnetic mold compound, had a thickness T_{MMC} of about 3.75 millimeters. The conductor portion 615 is mounted on the distal ends of the clips 611 and with the clips 611 forms the inductor 612, and the conductor portion 615 is surrounded by the magnetic mold compound 625, increasing the inductance.

FIG. 6G illustrates, in a projection view, an example where multiple conductor portions can be used to form inductors in example arrangements. In an example arrangement illustrated in FIGS. 6A, 6F, the conductor portions 615 can be staple or “U” shaped, although other shapes can be used. The conductor portions 615 can be a conductor material such as copper or copper alloy and can have an enamel protective insulating coating that is applied in a thermal process to form a robust insulator coating that can withstand temperature increases during use. In the example arrangement as shown in FIG. 6G, the microelectronic device package including the conductor portions 615 has a width labeled “P_{W}” of about 4 millimeters, the magnetic mold compound 625 has the thickness T_{MMC} of about 3.75 millimeters, and the package length labeled “P_{L}” of the microelectronic device package including the semiconductor die and the coils is about 6 millimeters.

In the illustrated example an inductor 612 includes two conductor portions 615 as shown that have a thickness of about 0.5 millimeters, a height labeled “C_{H}” of about 2.5 to 3.5 millimeters, and a width labeled “C_{W}” of about 2 millimeters. The conductive clips (see, for example, 611 in FIG. 6F) have exposed distal ends forming pads for mounting the conductor portions of an area of about 3 millimeters by 2 millimeters, the exposed end or pad area is made sufficiently large to assist in surface mounting the conductor portions 615 to the clips.

While the illustrated example microelectronic device package 600 has two conductor portions 615 that are coupled in series using the conductive clips and traces in the package substrate to form an inductor, more conductor portions such as three, four or more can be used, depending on the application and the inductor value needed. Further the dimensions of the conductor portions, such as the thickness, the height of the conductor portions C_{H}, and the width of the conductor portions C_{W}, can be varied. The overall package size such as the length P_{L} or the width P_{W} can be increased or decreased as needed for a given application. In a particular example with the total package size of about 4 millimeters by 6 millimeters and a total package thickness of about 4.2 millimeters, an inductor with a value of about 80 to 100 nanohenries (nH) was obtained. Other inductance values can be obtained by varying the dimensions of the coils and the number of coils used.

FIG. 6H illustrates the elements of FIG. 6G now including the package substrate 602, the semiconductor die 514, the EMC 623, the conductor portions 615, and the MMC 625 in a projection view. The two conductor portions 615 and clips 611 are coupled in series to form an inductor 612, the clips 611 can be coupled together using conductive traces in the package substrate 602 (not shown) for example. By extending the conductor portions 615 over the semiconductor die 514, the total area of the package is kept relatively small, and by using the MMC 625 for only a portion of the total mold compound, the cost of the package is reduced (when compared to a similar package formed using only MMC for the mold compound).

FIG. 6I illustrates, in three additional cross-sectional views, alternative conductor portion shapes that can be used to form inductors in additional arrangements. Conductor portion 670, for example, is a staple shape, with lower height than the staple shaped conductor portion 615 in FIG. 6G. The dimensions can vary, simulations or simple experiments can be used to obtain different inductance values. Conductor portion 672 is a “C” shape with extended bottom portions. Conductor portion 674 has a ladder shape with a middle element, which can increase the surface area exposed to the magnetic mold compound, and thereby increase the inductance obtained.

In the illustrated examples, the inductors are formed from conductor portions that are shaped as strips extending above and across the semiconductor die, with conductive clips supporting and electrically connecting to the conductor portions, and the conductor portions are surrounded by magnetic mold compound. In additional alternative arrangements where a larger package size is suitable, coils can be formed as the conductor portions over the semiconductor die and the coils of conductor material can have a magnetic core and can be surrounded by the magnetic mold compound, or can be partially surrounded by the magnetic mold compound, to form additional inductors useful with the arrangements. The magnetic mold compound is formed in a layer over the electronic mold compound that surrounds the semiconductor die, reducing the volume of the magnetic mold compound used.

In another arrangement that would use a slightly larger package size than the illustrated examples, instead of using flip chip mounted semiconductor dies, wire bonded semiconductor dies can be used, where the electrical connections from the semiconductor die to the package substate are formed as bond wires extending out from the semiconductor die to the leads of the package substrate.

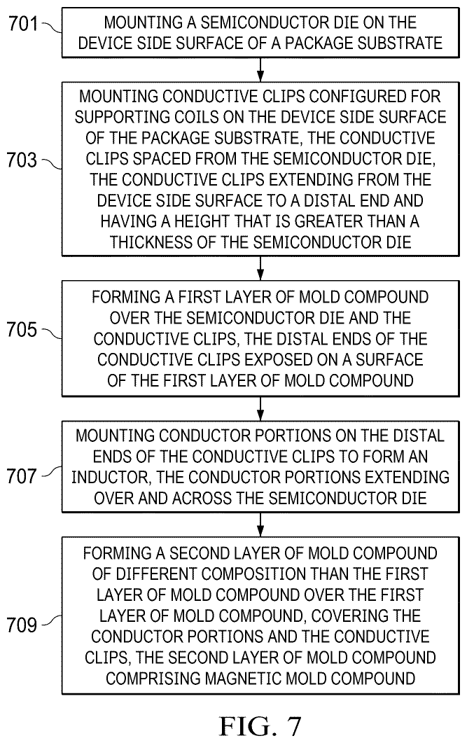

FIG. 7 illustrates, in a flow diagram, selected steps for a method for forming an example arrangement. The method begins at step 701 with mounting a semiconductor die on the device side surface of a package substrate (see, for example, the package substrate 602, and the flip chip mounted semiconductor die 514, in FIG. 6B).

At step 703, the method continues by mounting conductive clips configured for supporting conductor portions on the device side surface of the package substrate, the conductive clips spaced from the semiconductor die, the conductive clips extending from the device side surface to a distal end and having a height that is greater than a thickness of the semiconductor die (see, for example, the conductive clips 611 mounted on the device side surface of the package substrate 602 in FIG. 6C).

At step 705, the method continues by forming a first layer of mold compound over the semiconductor die and the conductive clips, the distal ends of the conductive clips exposed on a surface of the first layer of mold compound; (See, for example, the first layer of mold compound 623 in FIG. 6D, with the distal ends of the clips 611 exposed from the mold compound 623). As described above, in one approach the clips 611 are presoldered, so that solder will be present on the exposed ends. In another approach useful with the arrangements, solder can subsequently be deposited on the exposed ends of the clips, after the first layer of mold compound 623 is formed.

The method continues at step 707 in FIG. 7 by mounting conductor portions on the distal ends of the conductive clips to form an inductor, the conductor portions extending over and across the semiconductor die. (See, for example, the cross-section of FIG. 6E where a conductor portion 615 is shown mounted on clips 611 to form inductor 612). In a useful process, a solder reflow process forms a solder joint between the conductor portion 615 and the clips 611, note that in the examples, one, two or more conductor portions can be formed, the conductor portions and clips can be arranged to form an inductor coupled to the semiconductor die on the package substrate by the clips and by traces (not shown) in the package substrate. (See the two conductor portions 615 spaced apart in FIG. 6G, for example, and see the package 600 with the two conductor portions 615 shown in the projection view of FIG. 6H.)

Returning to FIG. 7, the method completes at step 709, by forming a second layer of mold compound of different composition than the first layer of mold compound over the first layer of mold compound, covering the conductor portions and the conductive clips, the second layer of mold compound including magnetic mold compound. (See, for example, the second layer of mold compound 625, of a magnetic mold compound, in FIG. 6F covering the first layer of mold compound 623 and having the metal particles 627 throughout the magnetic mold compound).

In the arrangements, the first layer of mold compound and the second layer of mold compound form a body for a microelectronic device package that integrates the conductor portions and the clips forming an inductor and the semiconductor die packaged together in a common function. In addition to the inductor and the semiconductor die shown in the illustrations, additional inductors, additional passive components, or additional semiconductor dies, can be mounted to the package substrate (or using die stacking, on the semiconductor die 514) and included in the microelectronic deice package to provide additional integration and functionality. Use of the arrangements provides a microelectronic device package that reduces the board area needed for a power function and reduces the need for users to design and provide the passive components to use the semiconductor die in a power circuit. Use of the arrangements with two layers of different mold compound advantageously reduces the amount of magnetic mold compound needed to implement the integrated inductor (when compared to prior approaches using only magnetic mold compound), reducing costs, and further advantageously isolates the package substrate and the semiconductor die from the magnetic mold compound, making the resulting microelectronic device packages using the arrangements more robust by reducing the possibility of arcing or shorts in the mold compound that can occur in a package formed with a prior approach.

Modifications are possible in the described examples, and other examples are possible, within the scope of the claims.

What is claimed is:

1. A method, comprising:
mounting a semiconductor die on a device side surface of a package substrate;
mounting conductive clips configured for supporting conductor portions on the device side surface of the package substrate, the conductive clips spaced from the semiconductor die, the conductive clips extending from the device side surface to a distal end and having a height that is greater than a thickness of the semiconductor die;
forming a first layer of mold compound over the semiconductor die and the conductive clips, the distal ends of the conductive clips exposed on a surface of the first layer of mold compound;
mounting conductor portions on the distal ends of the conductive clips to form an inductor, the conductor portions extending over and across the semiconductor die; and
forming a second layer of mold compound of different composition than the first layer of mold compound over the first layer of mold compound, covering the conductor portions and the conductive clips, the second layer of mold compound comprising magnetic mold compound.

2. The method of claim 1, wherein mounting conductor portions on the distal ends of the conductive clips further comprises mounting at least two conductor portions spaced from one another, the at least two conductor portions coupled together with the conductive clips forming the inductor that is coupled to the semiconductor die by traces on the package substrate.

3. The method of claim 1, wherein mounting a semiconductor die on the device side surface of a package substrate further comprises wherein the package substrate is a conductive leadframe.

4. The method of claim 1, wherein mounting a semiconductor die on the device side surface of a package substrate further comprises wherein the package substrate is a multilayer package substrate.

5. The method of claim 4, wherein the multilayer package substrate further comprises a build-up package substrate.

6. The method of claim 1, wherein prior to mounting conductive clips configured for supporting conductor portions on the device side surface of the package substrate, solder is deposited on the distal ends of the conductive clips.

7. The method of claim 1, wherein prior to mounting conductor portions on the distal ends of the conductive clips, solder is deposited on the distal ends of the conductive clips.

8. The method of claim 1, wherein the first layer of mold compound and the second layer of mold compound form a body of a microelectronic device package that covers the device side surface of the package substrate, the semiconductor die, the conductor portions and the conductive clips of the inductor.

9. The method of claim 8, wherein the semiconductor die is covered by the first layer of mold compound and is isolated from the second layer of mold compound.

10. The method of claim 9, wherein the microelectronic device package is a quad flat no-lead package.

11. The method of claim 1, wherein mounting conductor portions on the distal ends of the conductive clips, the conductor portions extending over and across the semiconductor die further comprises mounting two or more conductor portions.

12. The method of claim 1, wherein mounting conductor portions on the distal ends of the conductive clips to form an inductor, the conductor portions extending over and across the semiconductor die further comprises mounting conductor portions that have a staple shape, a C shape, or a ladder shape when viewed in a cross-section.

13. An apparatus, comprising:
at least one semiconductor die mounted to the device side surface of a package substrate;
conductive clips mounted on the device side surface of the package substrate, the conductive clips spaced from the semiconductor die, the conducive clips extending from the device side surface to a distal end and having a height that is greater than a thickness of the semiconductor die;
a first layer of mold compound over the device side surface of the package substrate, the first layer of mold compound covering the semiconductor die, while the distal ends of the conductive clips are exposed from the first layer of mold compound;
conductor portions mounted on the distal ends of the conductive clips, the conductor portions extending over and across the semiconductor die, the conductor portions and the conductive clips forming an inductor; and
a second layer of mold compound of different composition than the first layer of mold compound formed over the first layer of mold compound, the second layer of mold compound comprising a magnetic mold compound surrounding the conductor portions of the inductor.

14. The apparatus of claim 13, wherein the conductor portions comprise at least two conductor portions spaced from one another and coupled in series to form the inductor, and the inductor is coupled to the semiconductor die.

15. The apparatus of claim 13, wherein the conductor portions have a C shape, a staple shape, or a ladder shape when viewed in a cross section.

16. The apparatus of claim 13, wherein the package substrate further comprises a conductive leadframe.

17. The apparatus of claim 16, wherein the package substrate further comprises a multilayer package substrate.

18. The apparatus of claim 17, wherein the multilayer package substrate further comprises a build-up multilayer package substrate.

19. The apparatus of claim 13, wherein the first layer of mold compound and the second layer of mold compound form the body of a microelectronic device package that includes the semiconductor die, the inductor, and the package substrate.

20. The apparatus of claim 19, wherein the microelectronic device package further comprises a quad flat no-lead package.

21. A microelectronic device package, comprising:
a conductive leadframe;
a semiconductor die mounted to a device side surface of the conductive leadframe;
conductive clips configured to mount conductor portions, the conductive clips mounted to the device side surface of the conductive leadframe, the conductive clips positioned on opposite sides of the semiconductor die and extending away from the device side surface of the package substrate to distal ends;
a first layer of mold compound covering the semiconductor die and the device side surface of the conductive leadframe, the conductive clips extending through the first layer of mold compound and the distal ends of the conductive clips exposed from the first layer of mold compound;
at least two conductor portions mounted on the distal ends of the conductive clips, the conductor portions positioned over and extending across the semiconductor die and electrically coupled together to form an inductor that is coupled to the semiconductor die; and
a second layer of mold compound of a different composition than the first layer of mold compound comprising magnetic mold compound over the first layer of mold compound and surrounding and covering the conductor portions of the inductor.

22. The microelectronic device package of claim 21, wherein the microelectronic device package further comprises a quad flat no-lead package, the conductive leadframe having a board side surface and portions of leads of the conductive leadframe exposed from the first layer of mold compound and forming terminals of the quad flat no-lead package.
